(19) United States
(12) Patent Application Publication
(10) Pub. No.: US 2025/0364767 A1
(43) Pub. Date: Nov. 27, 2025

(54) LASER SYSTEM AND METHOD FOR GENERATING SECONDARY RADIATION THROUGH INTERACTION OF A PRIMARY LASER BEAM WITH A TARGET MATERIAL

(71) Applicant: TRUMPF Laser GmbH, Schramberg (DE)

(72) Inventors: Daniel Flamm, Ludwigsburg (DE); Max Kahmann, Nufringen (DE); Julian Hellstern, Rottweil (DE); Christoph Tillkorn, Villingendorf (DE); Torsten Mans, Aachen (DE)

(21) Appl. No.: 19/298,222

(22) Filed: Aug. 13, 2025

Related U.S. Application Data
(63) Continuation of application No. PCT/EP2024/053624, filed on Feb. 13, 2024.

(30) Foreign Application Priority Data
Feb. 17, 2023 (DE) 10 2023 104 013.8

(51) Int. Cl. H01S 3/00; G21G 4/02; H01J 37/075; H01J 37/08; H05G 2/00

(52) U.S. Cl. CPC H01S 3/0071; G21G 4/02; H01J 37/075; H01J 37/08; H05G 2/0084; H05G 2/0086; H01J 2237/0213; H01J 2237/06358; H01J 2237/0815

(57) ABSTRACT

A laser system for generating secondary radiation through interaction of a focused primary laser beam with a target material includes a laser beam source for providing a raw laser beam, and a beam guidance device for forming the focused primary laser beam from the raw laser beam. The focused primary laser beam is directed towards a target region in order to interact with the target material arranged in the target region. The beam guidance device includes a beam focusing device configured to form the primary laser beam by focusing a laser beam entering the beam focusing device, which corresponds to the raw laser beam. The beam focusing device includes at least two mirror elements spaced apart from one another. The beam focusing device has a numerical aperture between 0.001 and 0.01 provided that the primary laser beam propagates in a medium with a refractive index of less than 1.01.

### CROSS REFERENCE TO RELATED APPLICATIONS

This application is a continuation of International Application No. PCT/EP2024/053624 (WO 2024/170566 A1), filed on Feb. 13, 2024, and claims benefit to German Patent Application No. DE 10 2023 104 013.8, filed on Feb. 17, 2023. The aforementioned applications are hereby incorporated by reference herein.

### FIELD

Embodiments of the invention relate to a laser system for generating secondary radiation through interaction of a focused primary laser beam with a target material.

Embodiments of the invention further relate to a method for generating secondary radiation through interaction of a focused primary laser beam with a target material.

### BACKGROUND

The development of high-intensity lasers in scientific applications has made great progress in recent decades, for example through the invention of chirp pulse amplification. Numerous laser facilities worldwide now reach peak intensities of up to 1022 W/cm², see for example the scientific publication Danson et al., “Petawatt and exawatt class lasers worldwide.”, High Power Laser Science and Engineering 7 (2019).

One possible application of these very high-intensity lasers is secondary sources (see, for example, Albert et al., “2020 Roadmap on Plasma Accelerators.”, New Journal of Physics 23.3 (2021): 031101). These are what are termed secondary beam sources, defined as electromagnetic radiation or particle radiation, which is created through the interaction of a primary beam source (primary laser beam) with matter (target material). Depending on the type of primary and secondary radiation, the interaction mechanism ranges from nuclear reactions to beam scattering.

A first industrial application of laser-induced secondary radiation was demonstrated with the generation of EUV light for lithography. Here, tin droplets are ionized by a CO2 laser pulse. Extreme ultraviolet (EUV) light is emitted from the plasma through inverse bremsstrahlung.

For example, the following secondary radiation can be generated with high-intensity lasers: electron radiation, photon/X-ray radiation, proton/ion radiation, neutron radiation, and higher harmonics. These forms of radiation allow numerous applications in science, medicine, defense and security technology, as well as industrial applications, such as tomography and metrology in the semiconductor industry. Furthermore, there are applications in the field of energy generation and energy management, such as nuclear fusion and denuclearization of fission waste. Examples of relativistic electron or neutron radiation are known from Albert et al., “Laser wakefield accelerator based light sources: potential applications and requirements.”, Plasma Physics and Controlled Fusion 56.8 (2014): 084015, and Anderson et al., “Research opportunities with compact accelerator-driven neutron sources.”, Physics Reports 654 (2016): 1-58). For successful industrialization of these applications, the primary laser beam at the location of the target material must have certain light field parameters, wherein a sufficiently high intensity of the primary laser beam and a scaling of the average power thereof are particularly important.

Regarding the generation of secondary radiation with ultra-high intensity lasers, the industrialization of beam guidance and focusing, which is necessary to provide a primary laser beam with appropriate light field parameters and at the same time enables an industrially suitable throughput, is currently unresolved. In the prior art, the raw laser beam provided by a laser beam source is usually adjusted in diameter by a transmissive telescope and then focused by off-axis parabolic mirrors onto the corresponding target for secondary beam generation. Transmissive optical elements limit the peak intensity of the laser radiation due to absorption. In addition, transmissive optical elements limit the scaling of the repetition rate due to difficult thermal management. Furthermore, in the case of high peak intensities, when a laser beam passes through transmissive optical elements, local phase changes can occur due to the Kerr effect, which influence the wavefront of the laser beam and degrade the beam quality thereof.

An EUV beam-generating device is known from WO 2014/044392 A1, comprising a vacuum chamber in which a target material can be arranged at a target position for generating EUV radiation, a beam guidance chamber for guiding a laser beam from a driver laser device in the direction of the target position, an intermediate chamber which is arranged between the vacuum chamber and the beam guidance chamber, a first window which can be closed off in a gas-tight manner in the intermediate chamber for the entry of the laser beam from the beam guidance chamber, and a second window which can be closed off in a gas-tight manner in the intermediate chamber for the exit of the laser beam into the vacuum chamber.

An EUV light source device is known from DE 10 2009 044 426 A1, which generates EUV light by irradiating a target material with a pulsed driver laser beam.

A further EUV light source device is known from US 2022/0206397 A1.

### SUMMARY

Embodiments of the present invention provide a laser system for generating secondary radiation through interaction of a focused primary laser beam with a target material. The laser system includes a laser beam source for providing a raw laser beam comprising ultra-short laser pulses, and a beam guidance device for forming the focused primary laser beam from the raw laser beam. The focused primary laser beam is directed towards a target region in order to interact with the target material arranged in the target region. The beam guidance device includes a beam focusing device configured to form the primary laser beam by focusing a laser beam entering the beam focusing device. The laser beam entering the beam focusing device corresponds to the raw laser beam. The beam focusing device includes at least two mirror elements spaced apart from one another. The beam focusing device has a numerical aperture between 0.001 and 0.01 provided that the primary laser beam propagates in a medium with a refractive index of less than 1.01.

### BRIEF DESCRIPTION OF THE DRAWINGS

Subject matter of the present disclosure will be described in even greater detail below based on the exemplary figures. All features described and/or illustrated herein can be used alone or combined in different combinations. The features and advantages of various embodiments will become apparent by reading the following detailed description with reference to the attached drawings, which illustrate the following:

FIG. 1 shows a schematic representation of an exemplary embodiment of a laser system;

FIG. 2 shows an exemplary embodiment of a beam adjusting device of the laser system in a cross-section parallel to the main propagation direction of laser beams guided through the beam adjusting device;

FIG. 3 shows a schematic representation of a parabolic mirror element with associated paraboloid in a cross-section parallel to the rotation axis of the paraboloid according to some embodiments; and

FIG. 4 shows an exemplary embodiment of a beam focusing device of the laser system in a cross-section parallel to the main propagation direction of laser beams guided through the beam focusing device.

### DETAILED DESCRIPTION

Embodiments of the invention provide a laser system and method, which enable the generation of secondary radiation with industrially suitable throughput, wherein the primary laser beam has the largest possible effective volume for interaction with the target material.

According to some embodiments, a laser system for generating secondary radiation through interaction of a focused primary laser beam with a target material includes a laser beam source for providing a raw laser beam which has ultra-short laser pulses, and a beam guidance device for forming the focused primary laser beam from the raw laser beam. The focused primary laser beam is directed towards a target region in order to interact with a target material arranged in the target region. The beam guidance device has a beam focusing device which is configured to form the primary laser beam by focusing a laser beam entering the beam focusing device. The laser beam entering the beam focusing device is based on the raw laser beam or corresponds to the raw laser beam. The beam focusing device has at least two spherical mirror elements spaced apart from one another. The beam focusing device has a numerical aperture between 0.001 and 0.01 provided that the primary laser beam propagates in a medium with a refractive index of less than 1.01.

A beam focusing device with a numerical aperture in the specified range has proven to be particularly advantageous in the laser system mentioned above for generating secondary radiation. Such numerical apertures enable the focusing of an entering laser beam into a focus with a relatively large focus diameter of, for example, approximately 150 μm. This allows the primary laser beam to be provided with a large effective volume, i.e., with a large spatial region in which the primary laser beam interacts with the target material to generate secondary radiation. This enables efficient generation of secondary radiation with high throughput.

The large focus diameter of the primary laser beam enables, in particular, efficient generation of higher harmonics (higher harmonics generation). Numerous higher harmonics of the laser frequency are observed through the interaction of a laser beam in the focus.

In particular, the laser system according to embodiments of the invention is suitable or configured to generate secondary radiation in the form of higher harmonics.

In particular, the beam focusing device has a numerical aperture in the above-mentioned range provided that the primary laser beam is in a medium with a refractive index between exactly 1 and less than 1.01 or between exactly 1 and the refractive index of air at standard conditions.

The numerical aperture of the beam focusing device is proportional to the sine of an angle between a longitudinal center axis and/or a main ray of the primary laser beam and the edge rays of the primary laser beam. The numerical aperture corresponds to the product of the sine of the specified angle and the refractive index of the medium in which the primary laser beam propagates when measuring the specified angle.

In the present case, the fact that a laser beam is based on another laser beam is to be understood in particular to mean that the laser beam results from or is formed by beam shaping and/or beam guidance from the other laser beam.

For example, the fact that the laser beam entering the beam focusing device is based on the raw laser beam means that the raw laser beam has already passed through one or more other components of the beam guidance device before entering the beam focusing device, such as a beam adjusting device and/or a beam correction device.

The beam focusing device is arranged in particular after a beam adjusting device and/or after a beam correction device of the beam guidance device.

For example, the raw laser beam is a collimated laser beam and/or a Gaussian laser beam.

In particular, it can be provided that the primary laser beam formed from the raw laser beam has ultra-short laser pulses.

The primary laser beam is in particular a Gaussian laser beam.

The mirror elements of the beam focusing device and/or the mirror elements of a beam adjusting device of the laser system each have, in particular, a reflective surface, wherein the mirror elements have, in particular, a highly reflective coating, such as a dielectric coating or an “enhanced gold” coating, to form the reflective surface. For example, the mirror elements can be designed as glass mirrors or metal mirrors, each with a dielectric coating, or as metal mirrors with an “enhanced gold” coating. It is also possible to design the mirror elements as glass mirrors with a metallic coating, such as an “enhanced gold” coating.

In particular, the mirror elements are not metal mirrors without a coating.

The beam guidance device is designed in particular for beam guiding and/or beam shaping of the raw laser beam to form the primary laser beam from the raw laser beam.

Among the mirror elements of the beam focusing device, in this case this refers in particular to the mirror elements of the beam focusing device which contribute to adjusting the diameter of the raw laser beam.

In particular, the laser beam entering the beam focusing device impinges upon the mirror elements of the beam focusing device one after the other to form the primary laser beam.

In particular, it can be provided that the primary laser beam has a focus which is positioned on the target material and/or in the target material and/or in the region of the target material. A sufficiently high radiation intensity can be provided at the focus of the primary laser beam to interact with the target material.

It can be advantageous if a focus of the primary laser beam has a focus diameter between 100 μm and 500 μm. This allows the focus to be formed with a large Rayleigh length, resulting in a large effective volume of the primary laser beam for interaction with the target material.

It can be advantageous if a beam path within the beam focusing device has no focus. The beam path is understood to mean, in particular, a beam path associated with the entering laser beam and the primary laser beam within the beam focusing device. This makes it possible to avoid particularly high intensities of laser radiation, which can occur in a focus of the beam path. This makes it possible to reduce or avoid the occurrence of nonlinearities in the beam path, which can occur in the focus due to the high intensities. These nonlinearities can affect the wavefront of the laser beam and degrade the beam quality thereof, making it less possible to focus the primary laser beam and reducing the maximum achievable intensity of the laser radiation available for interaction with the target material. As the beam path has no focus, the efficiency of generating secondary radiation can be increased. Furthermore, increased thermal stress on components of the laser system, which can also be avoided, can occur near a focus of the beam path.

It can be advantageous if the beam focusing device is designed as a reflective optic. This means in particular that the beam focusing device is realized by means of a reflective and/or reflection-based optical concept. This enables the focusing of laser beams which have laser pulses with high peak intensities.

The axis of symmetry of the beam focusing device runs, for example, parallel to the entering laser beam and parallel to an axis of symmetry of a first spherical mirror element of the beam focusing device, upon which the laser beam entering it impinges.

It can be advantageous if the diameter of the laser beam entering the beam focusing device is between 15 mm and 100 mm. In particular, the diameter is between 20 mm and 30 mm. This allows the primary laser beam formed from this laser beam to be focused into a focus with a relatively large focus diameter, which provides a large effective cross-section for interaction with the target material. Furthermore, a laser beam with this diameter enables a reduction of non-linear effects which can occur, for example, at a passage element when the laser beam is coupled into a gas-tight chamber if the beam focusing device is arranged in this chamber.

It can therefore be advantageous if the beam guidance device has a beam adjusting device which is configured to adjust the diameter of the laser beam entering the beam focusing device by changing a diameter of the raw laser beam entering the beam guidance device. This allows the laser beam entering the beam focusing device to be provided with a diameter in the advantageous range specified above. The diameter of the laser beam entering the beam focusing device can thus be adjusted to an optimal diameter for the beam focusing device, in particular to form a focus with the largest possible focus diameter.

For example, the raw laser beam entering the beam guidance device has a diameter between 10 mm and 20 mm. To create a focus with the largest possible focus diameter, it can be useful to increase the diameter of the beam before it enters the beam focusing device.

The beam adjusting device is designed in particular as a reflective optic.

It can be advantageous if the beam focusing device has a first mirror element upon which the laser beam entering it impinges, and the beam focusing device has a further mirror element from which the focused primary laser beam emanates, wherein at least one intermediate laser beam runs between the first mirror element and the further mirror element. This allows the primary laser beam to be formed with a large focus diameter.

The first mirror element of the beam focusing device is in particular a very first mirror element upon which the laser beam entering the beam focusing device impinges.

The further mirror element of the beam focusing device is in particular a final mirror element of the beam focusing device, from which the primary laser beam emanates and/or is emitted.

In particular, it can be provided that a longitudinal center axis of the laser beam entering the beam focusing device and/or a longitudinal center axis of the primary laser beam and/or a longitudinal center axis of the at least one intermediate laser beam lie in the same geometric plane.

In particular, the at least one intermediate laser beam has no focus. This results in the advantages mentioned above.

It is fundamentally possible for several intermediate laser beams to be present between a first mirror element of the beam focusing device, upon which the entering laser beam impinges, and a further mirror element of the beam focusing device, from which the primary laser beam emanates. For example, these intermediate laser beams can be convergent or divergent laser beams.

In particular, it can be provided that the first mirror element, upon which the laser beam entering the beam focusing device impinges, is a spherical mirror element. Spherical mirror elements can be manufactured in a technically simple manner with a good surface quality.

For the same reason, it can be advantageous if the further mirror element from which the primary laser beam emanates is a spherical mirror element.

In particular, it can be provided that the first mirror element of the beam focusing device, upon which the laser beam entering the beam focusing device impinges, is concave.

In particular, it can be provided that the further mirror element of the beam focusing device, upon which the laser beam entering the beam focusing device impinges, is convex.

In particular, it can be provided that the beam focusing device has exactly two spherical mirror elements. This results in a simple design of the beam focusing device with the smallest possible number of mirror elements, whereby the design is also known as the Schwarzschild configuration. It enables good compensation of imaging errors of the respective mirror elements.

In one embodiment, the beam focusing device then has a total of exactly two mirror elements. These two mirror elements are the two spherical mirror elements. This allows the beam focusing device to be designed compactly.

In particular, it can be provided that the laser pulses of the raw laser beam and/or the primary laser beam have a pulse duration between 10 fs and 300 fs.

In particular, it can be provided that the laser pulses of the raw laser beam and/or the primary laser beam have a pulse energy between 1 mJ and 20 mJ.

An average power of the raw laser beam and/or the primary laser beam is, for example, between 0.5 kW and 5.0 kW, for example 1.0 kW.

For example, the intensity of the primary laser beam in the focus is between 1013 W/cm² and 1015 W/cm² and in particular between 1*1014 W/cm² and 9*1014 W/cm².

A wavelength of the raw laser beam and/or the primary laser beam is, for example, between 500 nm and 2500 nm and preferably between 900 nm and 1100 nm, for example 1030 nm.

The parameters mentioned enable the generation of higher harmonics in a technically advantageous manner.

In particular, it can be provided that the laser system comprises the target region for arranging the target material and/or comprises the target material.

In particular, it can be provided that a negative pressure and in particular a vacuum is formed in the target region. For example, the target region is located within a gas-tight region of the laser system.

It can be provided that the laser system has a gas-tight chamber in which the target region for arranging the target material is positioned, wherein the chamber has a passage element for coupling a laser beam into the chamber. The primary laser beam is based on or corresponds to this laser beam. A negative pressure and in particular a vacuum is created in the chamber.

In particular, the passage element has an anti-reflective coating, which is preferably designed as a nanotexturing and/or as a moth-eye structure.

In particular, it can be provided that the beam focusing device is arranged at least partially within the chamber. This means in particular that at least one component of the beam focusing device, such as a mirror element of the beam focusing device, is positioned within the chamber. This can also mean that the beam focusing device is located entirely within the chamber.

It can be advantageous if the laser system has a shielding element which is arranged between the passage element and the target material, wherein the shielding element is configured for spatially shielding an optical component of the laser system. In particular, the shielding element is configured to spatially shield the passage element from the target material. By means of the shielding element, contamination of the optical component or the passage element by scattered target material during operation of the laser system can be reduced or avoided.

An optical component of the laser system is understood to be, for example, a transmissive or reflective optical element of the laser system, such as a mirror element of the beam focusing device or a beam expanding device.

The shielding element can be designed, for example, as a diaphragm element or as a bevel element, or can be realized by means of a fluid flow.

The target material arranged in the target region is in particular in a gaseous state.

For example, the target material is or comprises a noble gas such as xenon, argon, helium, or krypton.

It can be advantageous if the beam guidance device has a beam correction device for forming a corrected laser beam from a laser beam entering the beam correction device, wherein a beam position stabilization is carried out by means of the beam correction device in order to provide the corrected laser beam with a corrected and/or stabilized beam position. This enables stable positioning of a focus of the primary laser beam, which in turn enables stable and low-interference delivery of secondary radiation.

In particular, it can be provided that a wavefront correction of the laser beam entering it is carried out by means of the beam correction device in order to provide the corrected laser beam with a corrected wavefront. This allows the primary laser beam to be provided with increased beam quality.

In particular, the laser beam entering the beam correction device is based on the raw laser beam and/or on an adjusted laser beam formed by means of a beam adjusting device of the beam guidance device. In particular, the laser beam entering the beam correction device corresponds to this adjusted laser beam.

In particular, the laser beam entering the beam focusing device corresponds to or is based on the corrected laser beam.

It can be provided that the laser system has a secondary beam guidance device for beam guiding and/or beam shaping of formed secondary radiation. For example, the secondary radiation formed is guided by means of the secondary beam guidance device to a location where the secondary radiation is intended to be used.

Embodiments of the invention also provide a method for generating secondary radiation through interaction of a focused primary laser beam with a target material arranged in a target region. A raw laser beam having ultra-short laser pulses is provided by means of a laser beam source. The focused primary laser beam is formed from the raw laser beam by means of a beam guidance device. The focused primary laser beam is directed onto the target region and interacts with the target material arranged in the target region. The beam guidance device has a beam focusing device which forms the primary laser beam by focusing a laser beam entering the beam focusing device. The laser beam entering the beam focusing device is based on the raw laser beam or corresponds to the raw laser beam. The beam focusing device has at least two spherical mirror elements spaced apart from one another. The beam focusing device has a numerical aperture between 0.001 and 0.01, provided that the primary laser beam (104) propagates in a medium having a refractive index of less than 1.01.

The method according to the embodiments of the invention in particular has one or more features and/or advantages of the laser system according to embodiments of the invention. Advantageous embodiments have already been explained in connection with the laser system according to embodiments of the invention.

The method according to embodiments of the invention can be carried out in particular by means of the laser system according to embodiments of the invention. In particular, the method according to embodiments of the invention is carried out by means of the laser system according to embodiments of the invention.

In the context of the present application documents, diameters of laser beams and/or focus diameters are generally defined using the method of second-order moments according to ISO 11146-3.

By stating that a first device and/or a first element of the laser system is arranged to be downstream from a second device and/or a second element of the laser system, it is to be understood in the present case as meaning that the laser beams guided in the laser system, such as the raw laser beam and/or the laser beams based on the raw laser beam, and/or the primary laser beam chronologically first impinge upon the second device and/or the second element in time, and subsequently upon the first device and/or the first element. Then, the second device and/or the second element is arranged to be upstream of the first device and/or the first element. These specifications must always be in relation to the main propagation direction of the laser beams.

The following description of preferred embodiments serves to explain the invention in greater detail with reference to the drawings.

Elements that are the same or have equivalent functions are provided with the same reference symbols in all of the figures.

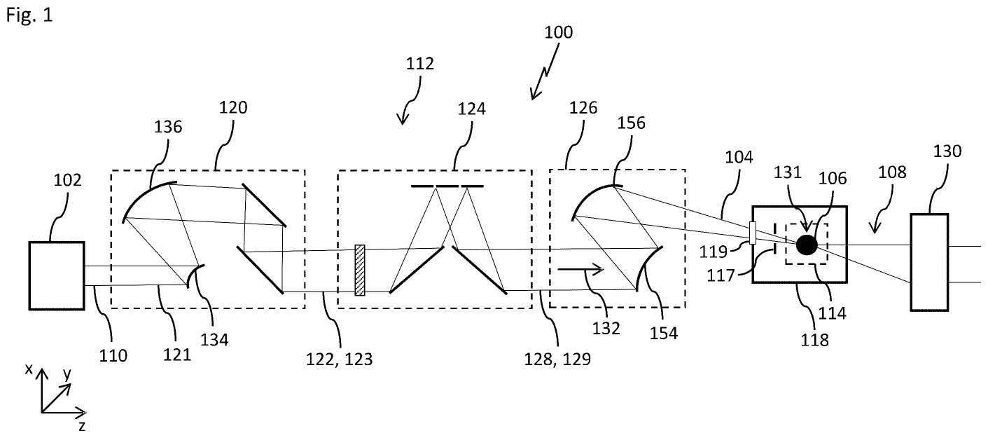

One exemplary embodiment of a laser system for generating a secondary beam is shown in FIG. 1 and designated 100 therein. The laser system 100 comprises a laser beam source 102, wherein a primary laser beam 104 is formed by beam shaping of a laser beam provided thereby. This is directed onto a target material 106, so that secondary radiation 108 is generated through interaction of the primary laser beam 104 with the target material 106.

In the example shown in FIG. 1, a raw laser beam 110 emerges from the laser beam source 102 during operation of the laser system 100. The laser system 100 has a beam guidance device 112 which is configured to form the primary laser beam 104 from the raw laser beam 110 and to direct it onto the target material 106 and/or to focus it into the target material 106. The target material 106 is arranged in a predetermined target region 114 of the laser system 100.

For example, the target material 106 is or comprises a gaseous material such as xenon, argon, helium, or krypton. In particular, the target material 106 is continuously introduced into the target region 114 by means of a suitable conveying device (not shown) in the form of a material flow and/or fluid flow, so that during operation of the laser system 100, the target material 106 is continuously available there for interaction with the primary laser beam 104.

It can be provided that a negative pressure, i.e., a pressure reduced compared to an ambient pressure, and in particular a vacuum, is formed in the target region 114. The target region 114 is located, for example, within a gas-tight region of the laser system 100. For example, the target region 114 is positioned within a gas-tight chamber 118 of the laser system 100, in which the gas-tight region and/or the negative pressure is formed.

For example, a gas with a defined pressure and defined composition can be arranged in the target region 114 and/or the gas-tight chamber 118.

In the example shown in FIG. 1, the chamber 118 comprises a passage element 119 through which the primary laser beam 104 enters the chamber 118. The passage element 119 is made of a material transparent to a wavelength of the primary laser beam 104. For example, the passage element 119 is designed as a vacuum window.

In particular, the passage element has an anti-reflective coating, such as a nanotexturing or a moth-eye structure. Such anti-reflective coatings are known, for example, in the scientific publication “Nanotextured optical surfaces advance laser power and reliability.” by Nole, et al., Laser Focus World 50.6 (2014): 38-43.

It can be provided that the beam focusing device 126 is arranged at least partially within the chamber 118 and/or within the gas-tight region.

In one embodiment, a shielding element 117 is arranged within the chamber 118, which is positioned between the passage element 119 and the target material 106, wherein the primary laser beam 104 passes through the shielding element 117. To allow the primary laser beam 104 to pass through, the shielding element 117 has a transmission region and/or an opening.

The shielding element 117 is configured to shield the passage element 119 from the target material 106. For example, the passage element 119 is shielded by means of the shielding element 117 from the target material 106, which is scattered and/or distributed in the direction of the passage element 119 during operation of the laser system 100.

For example, the shielding element 117 is designed as a diaphragm element and in particular as a pinhole diaphragm. Alternatively, the shielding element 117 can be designed as a bevel element or can be realized by means of a fluid flow, and in particular a gas flow.

The raw laser beam 110 is a pulsed laser beam which has ultra-short laser pulses (ultra-short pulse laser beam). The laser pulses preferably have a pulse duration between 10 fs and 300 fs and/or a pulse energy between 1 mJ and 20 mJ. A wavelength of the raw laser beam 110 is preferably between 500 nm and 2500 nm, and the raw laser beam 110 preferably has an average power in the range of 0.5 kW to 5 kW.

For example, the laser beam source 102 is a solid-state ultra-short pulse laser beam source, which has, for example, a Ti: Sa or an ytterbium-doped YAG amplifier.

The raw laser beam 110 emerging from the laser beam source 102 is in particular a collimated laser beam and/or Gaussian laser beam.

The beam guidance device 112 has a beam adjusting device 120, by means of which an adjusted laser beam 122 is formed by changing a diameter of a laser beam 121 entering it. In the embodiment according to FIG. 1, the raw laser beam 110 coupled out of the laser beam source 102 is coupled into the beam adjusting device 120 of the beam guidance device 112. The entering laser beam 121 thus corresponds to the raw laser beam 110 in the example shown.

Furthermore, in the example shown, the beam guidance device 112 comprises a beam correction device 124 and a beam focusing device 126 through which the adjusted laser beam 122 passes. In this embodiment, the laser beam emerging from the beam focusing device 126 corresponds to the primary laser beam 104 intended for interaction with the target material 106.

By means of the beam correction device 124, a correction is made of a laser beam 123 entering it, which in the example shown corresponds to the adjusted laser beam 122, wherein a corrected laser beam 128 is formed. The beam correction device 124 is configured to perform beam position stabilization in order to provide the corrected laser beam 128 with a corrected and/or stabilized beam position. The beam position stabilization comprises in particular a correction and/or stabilization of a spatial position of the corrected laser beam 128 in the near field and an angle of the corrected laser beam 128 in the far field.

For example, the beam correction device 124 has one or more piezo mirrors which are controlled by four-quadrant photodiodes to stabilize the spatial position and/or the angle of the corrected laser beam 128.

In addition, the beam correction device 124 can be configured to perform a wavefront correction of the entering laser beam 123 in order to provide the corrected laser beam 128 with a wavefront that is as flat as possible. Methods and devices for wavefront correction for laser beams with high intensities are known, for example, from S. Fourmaux, et al., “Laser beam wavefront correction for ultra high intensities with the 200 TW laser system at the Advanced Laser Light Source,” Opt. Express 16, 11987-11994 (2008).

The beam focusing device 126 is configured for beam shaping and/or focusing an entering laser beam 129, which in the example shown corresponds to the corrected laser beam 128. By means of the beam focusing device 126, the focused primary laser beam 104 directed onto the target material 106 is formed from the entering laser beam 129.

The primary laser beam 104 has a focus 131 arranged on the target material 106 with a defined focus diameter, which is, for example, approximately 150 μm. The focus diameter is understood to mean a transverse diameter and/or an extension of the primary laser beam 104 in the transverse direction.

By focusing the primary laser beam 104 onto and/or into the target material 106, the secondary radiation 108 is formed during operation of the laser system 100. It can be provided that the laser system 100 has a secondary beam guidance device 130 which is configured for beam guiding and/or beam shaping of the formed secondary radiation 108.

The primary laser beam 104 and the above-mentioned laser beams 121, 122, 123, 128, 129 are each based on the raw laser beam 110 and/or are formed by beam shaping of the raw laser beam 110.

The raw laser beam 110 and the laser beams based on the raw laser beam 110 each propagate with a main propagation direction 132. The main propagation direction 132 is a local property of a particular laser beam and is defined in particular by a direction of a Poynting vector or averaged Poynting vector associated with the laser beam. In the case of a collimated laser beam, the main propagation direction 132 is oriented, for example, parallel to a longitudinal center axis of the laser beam.

In the embodiment according to FIG. 1, the beam adjusting device 120 is arranged in front of the beam correction device 124 and/or in front of the beam focusing device 126. The beam correction device 124 is arranged, for example, in front of the beam focusing device 126 and/or between the beam adjusting device 120 and the beam focusing device 126.

A laser beam, such as the raw laser beam 110, the primary laser beam 104 and/or the laser beams 121, 122, 123, 128, 129, is generally understood to be a beam concentration which has a plurality of partial beams. These can, for example, be convergent, divergent or, in the case of a collimated laser beam, parallel to one another. The laser beams each have a transverse extension and/or a transverse beam cross-section, i.e., an extension or a cross-section in a direction perpendicular to the main propagation direction 132.

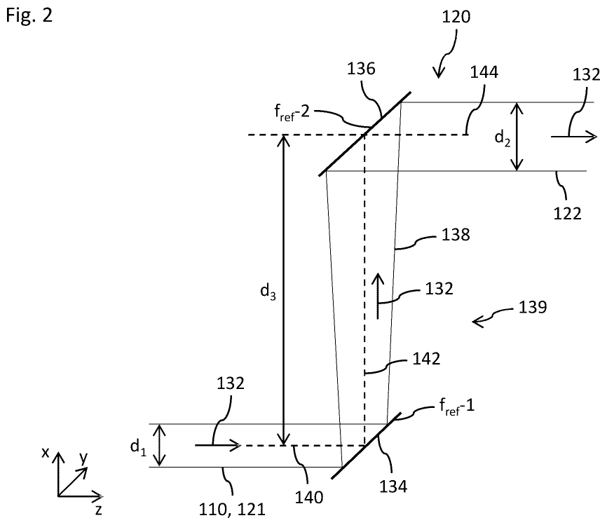

An exemplary embodiment of the beam adjusting device 120 is shown in FIG. 2. This has a first mirror element 134 and a second mirror element 136 spaced apart from the first mirror element 134. The mirror elements 134, 136 are configured to expand the raw laser beam 110 or the entering laser beam 121, i.e., to increase a diameter of the transverse beam cross-section of the raw laser beam 110 or the entering laser beam 121. The laser beam 122 adjusted by means of the mirror elements 134, 136 exits the beam adjusting device 120 and, in the example shown, is coupled into the beam correction device 124.

The entering laser beam 121 and the adjusted laser beam 122 are each present as collimated laser beams, wherein the entering laser beam 121 has a diameter d₁ and the adjusted laser beam 122 has a diameter d₂ (in FIG. 2, for example, a beam waist of the laser beams 121, 122 is indicated). The diameter d₂ is larger than the diameter d₁. The diameter d₁, d₂ is to be understood as a transverse diameter and/or a diameter of the transverse beam cross-section of the laser beams 121, 122.

In particular, the entering laser beam 121 and the adjusted laser beam 122 each have a rotationally symmetric and in particular circular transverse beam cross-section. In particular, a diameter of this beam cross-section is the same in every spatial direction which lies in a cross-sectional plane associated with the beam cross-section.

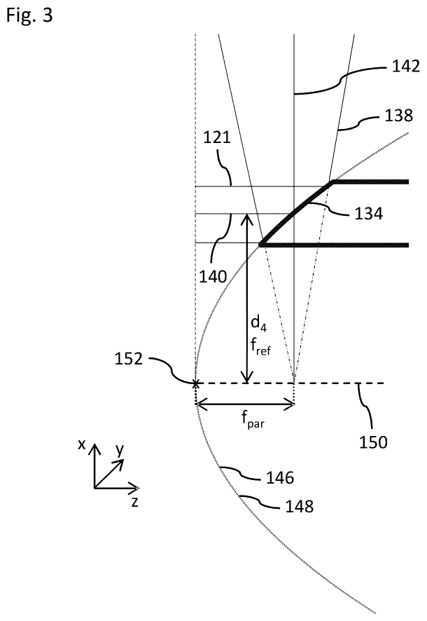

The mirror elements 134, 136 of the beam adjusting device 120 are each designed as off-axis parabolic mirrors. They each have curved and reflective surfaces (see FIG. 3). In an off-axis parabolic mirror, the reflecting surfaces do not contain the rotation axis of the respective paraboloid (and therefore also not the vertex of the paraboloid).

Preferably, the mirror elements 134, 136 have a highly reflective coating to form the reflective surfaces, such as a dielectric coating or an “enhanced gold” coating. For example, the mirror elements 134, 136 can be designed as glass mirrors or metal mirrors, each with a dielectric coating, or as metal mirrors with an “enhanced gold” coating. It can also be provided that the mirror elements 134, 136 are designed as glass mirrors with a metallic coating, such as an “enhanced gold” coating.

In particular, the mirror elements 134, 136 are not metal mirrors without a coating.

The entering laser beam 121 impinges upon the first mirror element 134 and is reflected therefrom, forming a reflected intermediate laser beam 138 which extends between the first mirror element 134 and the second mirror element 136. The intermediate laser beam 138 impinges upon the second mirror element 136 and is reflected therefrom, forming the adjusted laser beam 122 emerging from the beam adjusting device 120.

The path of the entering laser beam 121, the adjusted laser beam 122, and the intermediate laser beam 138 in the beam adjusting device 120 is referred to herein as the beam path 139.

The first mirror element 134 is convexly curved and the second mirror element 136 is concavely curved (with respect to a respective incident direction of the entering laser beam 121 and the intermediate laser beam 138).

Due to the convex curvature of the first mirror element 134, the intermediate laser beam 138 is formed as a divergent beam, i.e., the beam diameter thereof increases in the main propagation direction 132. It runs continuously as a divergent beam between the first mirror element 134 and the second mirror element 136. In particular, the intermediate laser beam 138 has no intermediate focus and/or no converging beam sections and/or no converging partial beams or beam components.

By means of the concave second mirror element 136, the divergent intermediate laser beam 138 incident thereon is transformed into the collimated, adjusted laser beam 132.

The entering laser beam 121 has a longitudinal center axis 140, the intermediate laser beam 138 has a longitudinal center axis 142, and the adjusted laser beam 122 has a longitudinal center axis 144. A course of the respective longitudinal center axis 140, 142, 144 corresponds to a course of a central partial beam (also referred to as main beam or “chief ray”) of the associated laser beam 121, 138, 122. Furthermore, the longitudinal center axis 140, 142, 144 is oriented to be parallel to the local main propagation direction 132 of the associated laser beam 121, 138, 122.

The longitudinal center axis 140 of the entering laser beam 121 and the longitudinal center axis 144 of the adjusted laser beam 122 are, for example, oriented to be parallel to one another. The longitudinal center axis 142 of the intermediate laser beam 138 is oriented, for example, to be perpendicular to the longitudinal center axis 140 of the entering laser beam 121 and/or to the longitudinal center axis 144 of the adjusted laser beam 122.

For example, the diameter d₁ has a value of 10.0 mm and the diameter d₂ has a value of 25.0 mm.

A distance d₃ by which the first mirror element 134 and the second mirror element 136 are spaced apart from one another is, for example, 500 mm.

A distance d₃ between the first mirror element 134 and the second mirror element 136 is, for example, 1500 mm. The distance d₃ corresponds to a distance between an intersection point of the longitudinal center axis 142 of the intermediate laser beam 138 with the surface of the first mirror element 134 and an intersection point of the longitudinal center axis 142 with the surface of the second mirror element 136. Consequently, the distance d₃ corresponds to a path length of the central partial beam (chief ray) of the intermediate laser beam 138 lying in the longitudinal center axis 142 between the first mirror element 134 and the second mirror element 136.

The parameters relevant for describing a mirror element designed as an off-axis parabolic mirror are illustrated in FIG. 3, wherein the situation present in the first mirror element 134 is shown as an example. Parabolic mirror elements can be generally described using the parameters introduced below.

The entering laser beam 121 impinges upon the first mirror element 134, wherein the intermediate laser beam 138 oriented to be perpendicular to the entering laser beam 121 is formed by reflection at the surface of the first mirror element 134.

The reflecting surface of the first mirror element 134 lies in a section of a paraboloid 146, which results from the rotation of a parabola 148 about a rotation axis 150. The parabola 148 is described by the function z(x)=c/2*x². In FIG. 3, the paraboloid 146 is shown in a cross-section lying in the rotation axis 150.

In the context of the application documents, a mirror element designed as an off-axis parabolic mirror is to be understood as a mirror element for which the reflective surface corresponds to a surface resulting from the rotation of the function z(x)=c/2*x², wherein deviations of a maximum of 1% from this function are permissible. In this case, a region of the mirror element must be considered in which at least 99% of the power of the laser beam incident on this mirror element is present.

The paraboloid 146 has an original focal length fₚₐᵣ (also called “parent focal length”) and a reflective focal length f_{ref} (“reflective focal length”). The reflective focal length f_{ref} is to be understood in particular as an effective focal length with respect to the entering laser beam 121.

In this case, the entering laser beam 121 and the intermediate laser beam 138 are oriented to be perpendicular to one another. In this case, fₚₐᵣ=1/c and f_{ref}=1/(2c). Furthermore, a distance d₄ between a vertex 152 of the paraboloid 146 and the longitudinal center axis 140 of the entering laser beam 121 corresponds to the reflective focal length f_{ref}. This distance d₄ is also called the “decenter” distance.

In the example shown in FIG. 2, the first mirror element 134 and the second mirror element 136 each have different reflective focal lengths. For example, a reflective focal length f_{ref}-1 of the first mirror element has a value of 500 mm and a reflective focal length f_{ref}-2 of the second mirror element 136 has a value of 1250 mm.

A magnification factor M of the beam adjusting device 120 generally corresponds to a quotient of the diameter d₂ of the adjusted laser beam 122 and the diameter d₁ of the entering laser beam 121. In the example described, this results in M=25.0 mm/10.0 mm=2.5. Furthermore, in the example shown, M=f_{ref}−2/f_{ref}−1=1250 mm/500 mm=2.5.

In the embodiment according to FIG. 2, the beam adjusting device 120 has two reflective mirror elements 134, 136. It is generally possible for the beam adjusting device to have more than two reflective mirror elements.

It is evident that the beam adjusting device 120 can also be configured or used to adjust the diameter d₁ of the entering laser beam 121. For this purpose, in the example shown in FIG. 2, the first mirror element 134 and the second mirror element 136 would have to be swapped so that the entering laser beam 121 first falls on the second mirror element 136 and the then formed intermediate laser beam 138 falls on the first mirror element 134. In this case, the magnification factor M<1, or the beam adjusting device 120 has a reduction factor which is defined as 1/M.

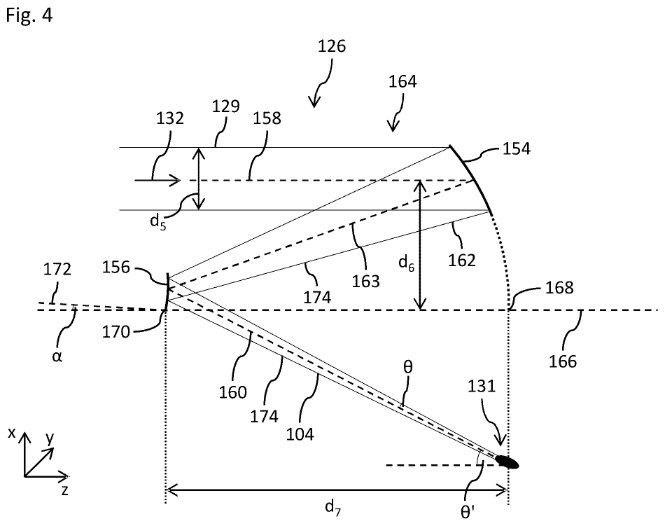

An exemplary embodiment of the beam focusing device 126 is shown in FIG. 4. This has a first mirror element 154 and a second mirror element 156 spaced apart from the first mirror element 154. The mirror elements 154, 156 are configured to focus the entering laser beam 129 to form the focused primary laser beam 104 directed onto the target material 106.

The entering laser beam 129 is in particular a collimated laser beam and has a diameter d₅ which, for example, corresponds to the diameter d₂ of the adjusted laser beam 122 emerging from the beam adjusting device 120.

The diameter d₅ is to be understood as a transverse diameter and/or a diameter of the transverse beam cross-section of the entering laser beam 129. In particular, the entering laser beam 129 has a rotationally symmetric and in particular circular transverse beam cross-section. In particular, a diameter of this beam cross-section is the same in every spatial direction which lies in a cross-sectional plane associated with the beam cross-section.

The primary laser beam 104 emerging from the beam focusing device 126 is present as a convergent and/or focused laser beam. It is focused in the focus 131.

The entering laser beam 129 has a longitudinal center axis 158 and the primary laser beam 104 has a longitudinal center axis 160, wherein the longitudinal center axis 158 and the longitudinal center axis 160 are oriented to be transverse to one another. In particular, the longitudinal central axes 158 and 160 enclose a non-zero angle.

The mirror elements 154, 156 of the beam focusing device 126 are each designed as spherical mirrors. They each comprise curved and reflective surfaces that have the shape of a spherical segment.

Preferably, the mirror elements 154, 156 have a highly reflective coating to form the reflective surfaces, such as a dielectric coating or an “enhanced gold” coating. For example, the mirror elements 154, 156 can be designed as glass mirrors or metal mirrors, each having a dielectric coating, or as metal mirrors with an “enhanced gold” coating. It can also be provided that the mirror elements 154, 156 are designed as glass mirrors with a metallic coating, such as an “enhanced gold” coating. In particular, the mirror elements 154, 156 are not metal mirrors without a coating.

The entering laser beam 129 impinges upon the first mirror element 154 and is reflected therefrom, forming a reflected intermediate laser beam 162 which extends between the first mirror element 154 and the second mirror element 156. The intermediate laser beam 162 impinges upon the second mirror element 156 and is reflected therefrom, forming the focused primary laser beam 104 emerging from the beam focusing device 126.

A longitudinal center axis 163 of the intermediate laser beam 162 is oriented to be transverse to the longitudinal center axis 158 of the entering laser beam 129 and/or to the longitudinal center axis 160 of the primary laser beam 104.

A course of the respective longitudinal center axis 158, 160, 163 corresponds to a course of a central partial beam (main beam or “chief ray”) of the respective associated laser beam 129, 104, 162. Furthermore, the longitudinal center axis 158, 160, 163 is oriented to be parallel to the local main propagation direction 132 of the associated laser beam 129, 104, 162.

The path of the entering laser beam 129, the primary laser beam 104, and the intermediate laser beam 162 in the beam focusing device 126 is referred to herein as the beam path 164.

The first mirror element 154 is concavely curved and the second mirror element 156 is convexly curved (with respect to a respective direction of incidence of the entering laser beam 129 and the intermediate laser beam 162).

Due to the concave curvature of the first mirror element 154, the intermediate laser beam 162 is formed as a convergent beam. It runs continuously as a convergent beam between the first mirror element 154 and the second mirror element 156. In particular, the intermediate laser beam 162 has no intermediate focus and/or no diverging beam sections and/or no diverging beam components.

By means of the convex second mirror element 156, the convergent intermediate laser beam 162 incident thereon is transformed and/or deflected into the convergent primary laser beam 104.

The reflective surface of the first mirror element 154 lies in a portion of a spherical surface which has an axis of symmetry 166 parallel to the main propagation direction 132 and/or longitudinal center axis 158 of the incident laser beam 129. This axis of symmetry 166 is referred to below as the axis of symmetry of the beam focusing device 126.

The axis of symmetry 166 passes through a center point (not shown) of a geometric sphere which is associated with the portion of the spherical surface in which the surface of the first mirror element 154 lies. An extension of this spherical surface associated with the first mirror element 154 intersects the axis of symmetry 166 at a first point 168. In particular, the focus 131 is positioned to be spaced apart from the axis of symmetry 166 and/or does not lie on the axis of symmetry 166.

The reflecting surface of the second mirror element 156 lies in a portion of a spherical surface which intersects the axis of symmetry 166 at a second point 170. A normal 172 of this spherical surface at the point 170 forms a non-vanishing angle α with the axis of symmetry 166 wherein the normal 172 and the axis of symmetry 166 lie in the same geometric plane.

The angle α is in particular oriented such that the normal 172 intersects the extension of the spherical surface associated with the first mirror element 154 in a section between the first point 168 and the longitudinal center axis 160 of the primary laser beam 104.

For example, the diameter d₅ of the entering laser beam 129 has a value of 25.0 mm.

For example, the first mirror element 154 has a radius of curvature of 537.9 mm and the second mirror element 156 has a radius of curvature of 39.0 mm.

The angle α, with which the first mirror element 154 and the second mirror element 156 are tilted relative to one another, is, for example, 9.2°.

A distance d₆ between the longitudinal center axis 158 of the entering laser beam 129 and the axis of symmetry 166 is, for example, 30 mm.

A distance d₇ between the first point 168 and the second point 170 and parallel to the axis of symmetry 166, is, for example, 250 mm.

The intermediate laser beam 162 and the primary laser beam 104 each have edge rays 174 which are defined by a maximum geometric extent of the reflective surface of the first mirror element 154. These edge rays 174 each originate from outer edges of the surface of the first mirror element 154. The edge rays 174 are in particular those rays of the intermediate laser beam 162 or primary laser beam 104 which have the greatest distance from the longitudinal center axis 163 or 160 at a specific point of the longitudinal center axis 163 or 160 in a distance direction oriented to be perpendicular to the longitudinal center axis 163 or 160.

The edge rays 174 of the primary laser beam 104 form an angle θ with the longitudinal center axis 160 thereof. A numerical aperture NA of the primary laser beam 104 results from NA=n*sin(θ), where n is a refractive index of a medium in which the primary laser beam 104 propagates. For example, the numerical aperture in a vacuum is (n≈1.0) NA=0.002.

Real laser beams have a Gaussian-like envelope, so that the effectively used numerical aperture can be smaller than the theoretical maximum usable numerical aperture NA, which results from NA=n*sin(θ). Typically, the effectively used numerical aperture is at least a factor of 2 smaller than the maximum usable numerical aperture.

An angle θ′ between the longitudinal center axis 160 of the primary laser beam 104 and the axis of symmetry 166 is, for example, 18.6°.

The laser system 100 functions as follows:
During operation of the laser system 100, the raw laser beam 110 exits the laser beam source 102 and is coupled into the beam guidance device 112. The raw laser beam 110 passes successively through the beam adjusting device 120, the beam correction device 124, and the beam focusing device 126. Here, the raw laser beam 110 is adjusted by means of the beam adjusting device 120, corrected and/or stabilized by means of the beam correction device 124, and shaped and/or focused by means of the beam focusing device 126, wherein the primary laser beam 104 is formed.

The focused primary laser beam 104 is directed onto the target material 106, whereby an interaction takes place between the target material 106 and the primary laser beam 104. A secondary radiation 108 is formed due to this interaction.

For example, the secondary radiation produced is electromagnetic radiation with a wavelength of approximately 13.5 nm.

The formed secondary radiation 108 is shaped by means of the secondary beam guidance device 130 and guided to a target at which use of the secondary radiation 108 is intended.

While subject matter of the present disclosure has been illustrated and described in detail in the drawings and foregoing description, such illustration and description are to be considered illustrative or exemplary and not restrictive. Any statement made herein characterizing the invention is also to be considered illustrative or exemplary and not restrictive as the invention is defined by the claims. It will be understood that changes and modifications may be made, by those of ordinary skill in the art, within the scope of the following claims, which may include any combination of features from different embodiments described above.

The terms used in the claims should be construed to have the broadest reasonable interpretation consistent with the foregoing description. For example, the use of the article “a” or “the” in introducing an element should not be interpreted as being exclusive of a plurality of elements. Likewise, the recitation of “or” should be interpreted as being inclusive, such that the recitation of “A or B” is not exclusive of “A and B,” unless it is clear from the context or the foregoing description that only one of A and B is intended. Further, the recitation of “at least one of A, B and C” should be interpreted as one or more of a group of elements consisting of A, B and C, and should not be interpreted as requiring at least one of each of the listed elements A, B and C, regardless of whether A, B and C are related as categories or otherwise. Moreover, the recitation of “A, B and/or C” or “at least one of A, B or C” should be interpreted as including any singular entity from the listed elements, e.g., A, any subset from the listed elements, e.g., A and B, or the entire list of elements A, B and C.

### LIST OF REFERENCE SYMBOLS

α Angle
θ Angle
θ Angle
d₁ Diameter
d₂ Diameter
d₃ Distance
d₄ Distance
d₅ Diameter
d₆ Distance
d₇ Distance
fₚₐᵣ Original focal length
f_{ref} Reflective focal length
f_{ref}-1 Reflective focal length
f_{ref}-2 Reflective focal length
100 Laser system
102 Laser beam source
104 Primary laser beam
106 Target material
108 Secondary beam
110 Raw laser beam
112 Beam guidance device
114 Target region
117 Shielding element
118 Chamber
119 Passage element
120 Beam adjusting device
121 Entering laser beam
122 Adjusted laser beam
123 Entering laser beam
124 Beam correction device
126 Beam focusing device
128 Corrected laser beam
129 Entering laser beam
130 Secondary beam guidance device
131 Focus
132 Main propagation direction
134 First mirror element
136 Second mirror element
138 Intermediate laser beam
139 Beam path
140 Longitudinal center axis
142 Longitudinal center axis
144 Longitudinal center axis
146 Paraboloid
148 Parabola
150 Rotation axis
152 Vertex
154 First mirror element
156 Second mirror element
158 Longitudinal center axis
160 Longitudinal center axis
162 Intermediate laser beam
163 Longitudinal center axis
164 Beam path
166 Axis of symmetry
168 First point
170 Second point
172 Normal
174 Edge ray

1. A laser system for generating secondary radiation through interaction of a focused primary laser beam with a target material, the laser system comprising:
a laser beam source for providing a raw laser beam comprising ultra-short laser pulses, and
a beam guidance device for forming the focused primary laser beam from the raw laser beam, wherein the focused primary laser beam is directed towards a target region in order to interact with the target material arranged in the target region,
wherein the beam guidance device comprises a beam focusing device configured to form the primary laser beam by focusing a laser beam entering the beam focusing device, wherein the laser beam entering the beam focusing device corresponds to the raw laser beam,
wherein the beam focusing device comprises at least two mirror elements spaced apart from one another, and
wherein the beam focusing device has a numerical aperture between 0.001 and 0.01 provided that the primary laser beam propagates in a medium with a refractive index of less than 1.01.

2. The laser system according to claim 1, wherein a focus of the primary laser beam has a focus diameter of at least 100 μm and/or at most 500 μm.

3. The laser system according to claim 1, wherein a beam path within the beam focusing device has no focus.

4. The laser system according to claim 1, wherein a diameter of the laser beam entering the beam focusing device is between 15 mm and 100 mm.

5. The laser system according to claim 4, wherein the beam guidance device comprises a beam adjusting device configured to adjust the diameter of the laser beam entering the beam focusing device by changing a diameter of the raw laser beam entering the beam guidance device.

6. The laser system according to claim 1, wherein the at least two mirror elements of the beam focusing device comprise a first mirror element upon which the laser beam impinges, and a further mirror element from which the focused primary laser beam emanates, wherein at least one intermediate laser beam runs between the first mirror element and the further mirror element.

7. The laser system according to claim 6, wherein the first mirror element upon which the laser beam entering the beam focusing device impinges is a first spherical mirror element, and/or the further mirror element from which the primary laser beam emanates is a second spherical mirror element.

8. The laser system according to claim 6, wherein the first mirror element upon which the laser beam entering the beam focusing device impinges is concave, and/or the further mirror element from which the primary laser beam emanates is convex.

9. The laser system according to claim 1, wherein the laser pulses of the raw laser beam have a pulse duration of between 10 fs and 300 fs, and/or that the laser pulses of the raw laser beam have a pulse energy of between 1 mJ and 20 mJ.

10. The laser system according to claim 1, wherein a wavelength of the raw laser beam is between 500 nm and 2500 nm.

11. The laser system according to claim 1, comprising a gas-tight chamber in which the target region for arranging the target material is positioned, wherein the gas chamber comprises a passage element for coupling into the gas chamber a further laser beam which corresponds to the primary laser beam, and wherein a negative pressure is formed in the gas chamber.

12. The laser system according to claim 11, wherein the passage element has an anti-reflective coating.

13. The laser system according to claim 11, further comprising a shielding element arranged between the passage element and the target material, wherein the shielding element is configured for spatially shielding an optical component of the laser system from the target material.

14. The laser system according to claim 1, wherein the beam guidance device comprises a beam correction device for forming a corrected laser beam from a laser beam entering the beam correction device, wherein the beam correction device is configured to perform a beam position stabilization in order to provide the corrected laser beam with a corrected and/or stabilized beam position.

15. The laser system according to claim 14, wherein the beam correction device is configured to perform a wavefront correction of the laser beam entering the beam correction device.

16. A method for generating secondary radiation through interaction of a focused primary laser beam with a target material arranged in a target region, the method comprising:
providing a raw laser beam comprising ultra-short laser pulses by using a laser beam source, and
forming the focused primary laser beam from the raw laser beam by using a beam guidance device, wherein the focused primary laser beam is directed onto the target region and interacts with the target material arranged in the target region,
wherein the beam guidance device comprises a beam focusing device configured to form the primary laser beam by focusing a laser beam entering the beam focusing device, wherein the laser beam entering the beam focusing device corresponds to the raw laser beam,
wherein the beam focusing device comprises at least two spherical mirror elements spaced apart from one another, and
wherein the beam focusing device has a numerical aperture between 0.001 and 0.01 provided that the primary laser beam propagates in a medium with a refractive index of less than 1.01.
